(19) United States
(12) Patent Application Publication
(10) Pub. No.: US 2019/0265544 A1
(43) Pub. Date: Aug. 29, 2019

(54) MASK PLATE, DISPLAY SUBSTRATE AND METHOD FOR MANUFACTURING THE SAME, DISPLAY PANEL AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei (CN)

(72) Inventors: Qiang Ji, Beijing (CN); Guoqiang Zhong, Beijing (CN); Sangman Yuk, Beijing (CN); Haibin Yin, Beijing (CN); Jian Chen, Beijing (CN); Wenhao Tang, Beijing (CN); Anxin Dong, Beijing (CN)

(21) Appl. No.: 16/123,734

(22) Filed: Sep. 6, 2018

(30) Foreign Application Priority Data
Feb. 28, 2018 (CN) 201810168296.6

(51) Int. Cl. G02F 1/1335; G02F 1/1339; G02F 1/1343; G03F 1/54; G03F 7/00; G03F 7/038; G03F 7/20; G03F 7/26; G03F 7/039; G03F 7/16

(52) U.S. Cl. CPC G02F 1/133516; G02F 1/13394; G02F 1/133512; G02F 1/13439; G03F 1/54; G02F 2201/121; G03F 7/038; G03F 7/20; G03F 7/26; G03F 7/039; G03F 7/16; G03F 7/0007

(57) ABSTRACT

The present disclosure provides a mask plate for manufacturing a display substrate. The mask plate includes a light transmission pattern corresponding to a color filtering unit of the display substrate, a first partial light transmission pattern corresponding to a black matrix pattern of the display substrate, and an opaque pattern corresponding to a first spacer of the display substrate.

### CROSS-REFERENCE TO RELATED APPLICATION

This application is based on and claims priority of Chinese Patent Application No. 201810168296.6, filed on Feb. 28, 2018, which is incorporated herein by reference in its entirety.

### BACKGROUND

The present disclosure relates to the field of display technology, and in particular to a mask plate, a display substrate and a method for manufacturing the same, as well as a display panel and a display device.

A liquid crystal display device can be composed of an array substrate, a display substrate and a liquid crystal layer between the two substrates. Such a liquid display device has a variety of display modes. Twisted nematic (TN) mode liquid crystal display devices are widely used in mainstream low-end LCD displays at the current market, due to their advantages such as few output gray scale levels, fast response time and low production cost.

The manufacturing process in related art for display substrates of the TN mode liquid crystal display devices includes multiple patterning processes, resulting in long production cycle of the display substrates, limited production capacity, and high production cost.

### SUMMARY

According to one aspect, one embodiment of the present disclosure provides a mask plate for manufacturing a display substrate. The mask plate includes: a light transmission pattern that is corresponding to a color filtering unit of the display substrate; a first partial light transmission pattern that is corresponding to a black matrix pattern of the display substrate; and an opaque pattern that is corresponding to a first spacer of the display substrate.

Further, the mask plate further includes a second partial light transmission pattern that is corresponding to a second spacer of the display substrate; the second partial light transmission pattern has a light transmittance less than a light transmittance of the first partial light transmission pattern.

Further, the light transmittance of the first partial light transmission pattern is 30%-50%, and the light transmittance of the second partial light transmission pattern is 10%-18%.

One embodiment of the present disclosure further provides a mask plate for manufacturing a display substrate. The mask plate includes: an opaque pattern that is corresponding to a color filtering unit of the display substrate; a first partial light transmission pattern that is corresponding to a black matrix pattern of the display substrate; and a light transmission pattern that is corresponding to a first spacer of the display substrate.

Further, the mask plate further includes a second partial light transmission pattern that is corresponding to a second spacer of the display substrate; the second partial light transmission pattern has a light transmittance greater than a light transmittance of the first partial light transmission pattern.

Further, the light transmittance of the second partial light transmission pattern is 30%-50%, and the light transmittance of the first partial light transmission pattern is 10%-18%.

One embodiment of the present disclosure further provides a method for manufacturing a display substrate. The method includes: simultaneously forming a black matrix pattern and a first spacer of the display substrate with the above mask plate through one exposure development process.

The method can further include simultaneously forming a black matrix pattern and a first spacer of the display substrate with the mask plate through one exposure development process includes: forming a light-shielding positive photoresist material layer; exposing the positive photoresist material layer with the mask plate; after developing, removing a portion of the positive photoresist material layer, that is corresponding to the light transmission pattern; removing a portion of the positive photoresist material layer, that is corresponding to the first partial light transmission pattern, thereby forming the black matrix layer; and retaining a portion of the positive photoresist material layer, that is corresponding to the opaque pattern, thereby forming the first spacer; or, forming a light-shielding negative photoresist material layer; exposing the negative photoresist material layer with the mask plate; after developing, retaining a portion of the negative photoresist material layer, that is corresponding to the light transmission pattern, thereby forming the first spacer; removing a portion of the negative photoresist material layer, that is corresponding to the first partial light transmission pattern, thereby forming the black matrix layer; and removing a portion of the negative photoresist material layer, that is corresponding to the opaque pattern.

The method can further include forming a light-shielding positive photoresist material layer, and exposing the positive photoresist material layer with the mask plate; after developing, removing a portion of the positive photoresist material layer, that is corresponding to the light transmission pattern; removing a portion of the positive photoresist material layer, that is corresponding to the first partial light transmission pattern, thereby forming the black matrix layer; removing a portion of the positive photoresist material layer, that is corresponding to the second partial light transmission pattern, thereby forming the second spacer; and retaining a portion of the positive photoresist material layer, that is corresponding to the opaque pattern, thereby forming the first spacer; wherein a height of the second spacer is less than a height of the first spacer, and is greater than a height of the black matrix layer; or, forming a light-shielding negative photoresist material layer; exposing the negative photoresist material layer with the above mask plate; after developing, retaining a portion of the negative photoresist material layer, that is corresponding to the light transmission pattern, thereby forming the first spacer; removing a portion of the negative photoresist material layer, that is corresponding to the first partial light transmission pattern, thereby forming the black matrix layer; removing a portion of the negative photoresist material layer, that is corresponding to the second partial light transmission pattern, thereby forming the second spacer; and removing a portion of the negative photoresist material layer, that is corresponding to the opaque pattern; wherein a height of the second spacer is less than a height of the first spacer, and is greater than a height of the black matrix layer.

The method can further include, after simultaneously forming a black matrix pattern and a first spacer of the display substrate with the mask plate through one exposure development process, the method further includes: forming a color filtering unit in pixel areas defined by the black matrix pattern; and covering the color filtering unit with a transparent conductive layer.

The method can further include, before simultaneously forming a black matrix pattern and a first spacer of the display substrate with the mask plate through one exposure development process, the method further includes: forming a color filtering unit on a base substrate. After the simultaneously forming a black matrix pattern and a first spacer of the display substrate with the mask plate through one exposure development process, the method further includes: forming a transparent conductive layer.

### BRIEF DESCRIPTION OF THE DRAWINGS

A brief introduction will be given hereinafter to the accompanying drawings which will be used in the description of the embodiments in order to explain the embodiments of the present disclosure more clearly. Apparently, the drawings in the description below are merely for illustrating some embodiments of the present disclosure. Those skilled in the art may obtain other drawings according to these drawings without paying any creative labor.

FIG. 1 is a schematic view of a mask plate according to an embodiment of the present disclosure.

FIG. 2 is another schematic view of a mask plate according to an embodiment of the present disclosure.

FIG. 3 is a schematic diagram showing using the mask plate to expose a photoresist material layer according to an embodiment of the present disclosure.

FIG. 4 to FIG. 8 are schematic diagrams showing a process of manufacturing a display substrate according to an embodiment of the present disclosure.

FIG. 9 to FIG. 11 are schematic diagrams showing another process of manufacturing a display substrate according to an embodiment of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise indicated. The following description of exemplary embodiments is merely used to illustrate the present disclosure and is not to be construed as limiting the present disclosure.

With respect to the problems of long production cycle of the display substrates, limited production capacity and high production cost in the related art, embodiments of the present disclosure provide a mask plate, a display substrate, a method for manufacturing the same, a display panel, and a display device, which can improve productivity of the display substrates and reduce production cost of the display substrates.

One embodiment of the present disclosure provides a mask plate for manufacturing a display substrate. As shown in FIG. 1, the mask plate 1 includes a light transmission pattern 11 that is corresponding to a color filtering unit of the display substrate, a first partial light transmission pattern 12 that is corresponding to a black matrix pattern of the display substrate, and an opaque pattern 13 that is corresponding to a first spacer of the display substrate.

In this embodiment, in the mask plate 1, the light transmission pattern 11 is corresponding to the color filtering unit of the display substrate, the first partial light transmission pattern 12 is corresponding to the black matrix pattern of the display substrate, and the opaque pattern 13 is corresponding to the first spacer of the display substrate. Then, after a light-shielding positive photoresist material layer is coated on a base substrate, the positive photoresist material layer is exposed with the mask plate 1, thereby forming the black matrix pattern and the first spacer by means of one exposure development process. This can reduce a quantity of patterning processes for manufacturing the display substrate, thereby improving productivity of the display substrate and reducing production cost of the display substrate.

Further, the mask plate 1 further includes a second partial light transmission pattern that is corresponding to a second spacer of the display substrate. The second partial light transmission pattern has a light transmittance less than a light transmittance of the first partial light transmission pattern 12. Then, after the light-shielding positive photoresist material layer is coated on the base substrate, the positive photoresist material layer is exposed with the mask plate 1, thereby forming the black matrix pattern, the first spacer and the second spacer of the display substrate by means of one exposure development process. A height of the second spacer is less than a height of the first spacer. The formation of two spacers of different heights can maintain a cell thickness of a liquid crystal display device in a better manner.

Specifically, the light transmittance of the first partial light transmission pattern 12 is 30%-50%, the light transmittance of the second partial light transmission pattern is 10%-18%. When the light transmittance of the first partial light transmission pattern 12 is in the above range, the black matrix pattern manufactured through the mask plate 1 has a height that may well define pixel areas. When the light transmittance of the second partial light transmission pattern is in the above range, the second spacer manufactured through the mask plate 1 can cooperate with the first spacer to maintain the cell thickness of the liquid crystal display device in a better manner.

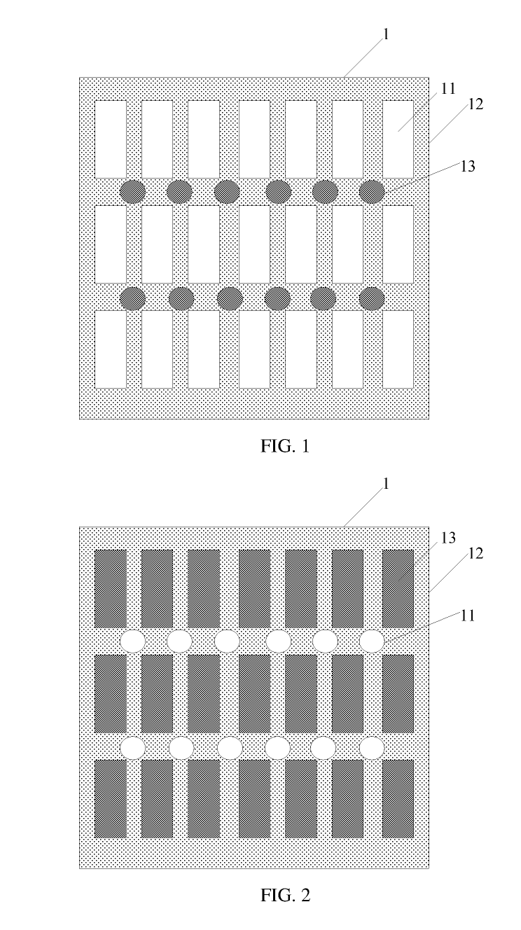

One embodiment of the present disclosure further provides a mask plate for manufacturing a display substrate. As shown in FIG. 2, the mask plate 1 includes an opaque pattern 13 that is corresponding to a color filtering unit of the display substrate, a first partial light transmission pattern 12 that is corresponding to a black matrix pattern of the display substrate, and a light transmission pattern 11 that is corresponding to a first spacer of the display substrate.

In this embodiment, in the mask plate 1, the opaque pattern, i.e., light-shading pattern, is corresponding to a color filtering unit of the display substrate, the first partial light transmission pattern 12 is corresponding to the black matrix pattern of the display substrate, and the light transmission pattern 11 is corresponding to the first spacer of the display substrate. Then, after a light-shielding negative photoresist material layer is coated on a base substrate, the negative photoresist material layer is exposed with the mask plate 1, thereby forming the black matrix pattern and the first spacer by means of one exposure development process. This can reduce a quantity of patterning processes for manufacturing the display substrate, thereby improving productivity of the display substrate and reducing production cost of the display substrate.

Further, the mask plate 1 further includes a second partial light transmission pattern that is corresponding to a second spacer of the display substrate. The second partial light transmission pattern has a light transmittance greater than a light transmittance of the first partial light transmission pattern 12. Then, after the light-shielding negative photoresist material layer is coated on the base substrate, the negative photoresist material layer is exposed with the mask plate 1, thereby forming the black matrix pattern, the first spacer and the second spacer of the display substrate by means of one exposure development process. A height of the second spacer is less than a height of the first spacer. The formation of two spacers of different heights can maintain a cell thickness of a liquid crystal display device in a better manner.

Specifically, the light transmittance of the second partial light transmission pattern is 30%-50%, the light transmittance of the first partial light transmission pattern is 10%-18%. When the light transmittance of the first partial light transmission pattern 12 is in the above range, the black matrix pattern manufactured through the mask plate 1 has a height that may well define pixel areas. When the light transmittance of the second partial light transmission pattern is in the above range, the second spacer manufactured through the mask plate 1 can cooperate with the first spacer to maintain the cell thickness of the liquid crystal display device in a better manner.

One embodiment of the present further provides a method for manufacturing a display substrate. The method uses the above mask plate to simultaneously form the black matrix pattern and the first spacer of the display substrate by means of one exposure development process.

In this embodiment, simultaneously forming the black matrix pattern and the first spacer of the display substrate by means of one exposure development process can reduce a quantity of patterning processes for manufacturing the display substrate, thereby improving productivity of the display substrate and reducing production cost of the display substrate.

In one embodiment, the method includes: forming a light-shielding positive photoresist material layer; exposing the positive photoresist material layer with the mask plate 1 as shown in FIG. 1; after developing, removing a portion of the positive photoresist material layer, that is corresponding to the light transmission pattern 11; removing a portion of the positive photoresist material layer, that is corresponding to the first partial light transmission pattern 12, thereby forming the black matrix layer; and retaining a portion of the positive photoresist material layer, that is corresponding to the opaque pattern 13, thereby forming the first spacer.

In this embodiment, in the mask plate 1, the light transmission pattern 11 is corresponding to the color filtering unit of the display substrate, the first partial light transmission pattern 12 is corresponding to the black matrix pattern of the display substrate, and the opaque pattern 13 is corresponding to the first spacer of the display substrate. Then, after a light-shielding positive photoresist material layer is coated on a base substrate, the positive photoresist material layer is exposed with the mask plate 1, thereby forming the black matrix pattern and the first spacer by means of one exposure development process. This can reduce a quantity of patterning processes for manufacturing the display substrate, thereby improving productivity of the display substrate and reducing production cost of the display substrate.

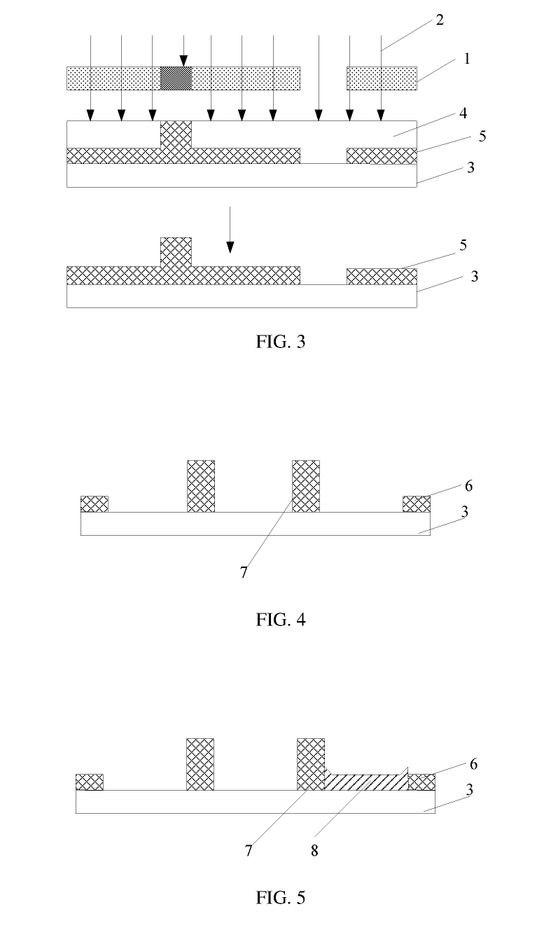

As shown in FIG. 3, after a positive photoresist material layer is coated on a base substrate 3, the positive photoresist material layer is covered by the mask plate 1; meanwhile, ultraviolet light 2 is used to expose the positive photoresist material layer. As a result, a portion of the positive photoresist material layer, that is covered by the opaque pattern 13, is not exposed and then forms an un-exposed photoresist material layer 5; portions of the positive photoresist material layer, that are covered by the first partial light transmission pattern 12 and the light transmission pattern 11, are exposed and then form an exposed photoresist material layer 4. After developing, the exposed photoresist material layer 4 is removed, thereby forming two photoresist material layers of different heights on the base substrate 3. In this way, when manufacturing the display substrate with the light-shading photoresist material layer, two light-shading layers of different heights may be formed through one exposure development process. The lower light-shading layer may be taken as the black matrix pattern of the display substrate, and the higher light-shading layer may be taken as the spacer of the display substrate, thereby forming the black matrix pattern and the first spacer by means of one exposure development process. This can reduce a quantity of patterning processes for manufacturing the display substrate, thereby improving productivity of the display substrate and reducing production cost of the display substrate.

In another embodiment, the method includes: forming a light-shielding negative photoresist material layer; exposing the negative photoresist material layer with the mask plate 1 as shown in FIG. 2; after developing, retaining a portion of the negative photoresist material layer, that is corresponding to the light transmission pattern 11, thereby forming the first spacer; removing a portion of the negative photoresist material layer, that is corresponding to the first partial light transmission pattern 12, thereby forming the black matrix layer; and removing a portion of the negative photoresist material layer, that is corresponding to the opaque pattern 13.

In this embodiment, when the mask plate 1 includes the opaque pattern, i.e., light-shading pattern, that is corresponding to the color filtering unit of the display substrate, the first partial light transmission pattern 12 that is corresponding to the black matrix pattern of the display substrate, and the light transmission pattern 11 that is corresponding to the first spacer of the display substrate, after a light-shielding negative photoresist material layer is coated on a base substrate, the negative photoresist material layer is exposed with the mask plate 1, thereby forming the black matrix pattern and the first spacer by means of one exposure development process. This can reduce a quantity of patterning processes for manufacturing the display substrate, thereby improving productivity of the display substrate and reducing production cost of the display substrate.

Further, when the mask plate 1 further includes a second partial light transmission pattern that is corresponding to a second spacer of the display substrate, and the second partial light transmission pattern has a light transmittance less than a light transmittance of the first partial light transmission pattern, the method specifically includes: forming a light-shielding positive photoresist material layer, and exposing the positive photoresist material layer with the above mask plate 1; after developing, removing a portion of the positive photoresist material layer, that is corresponding to the light transmission pattern 11; removing a portion of the positive photoresist material layer, that is corresponding to the first partial light transmission pattern 12, thereby forming the black matrix layer; removing a portion of the positive photoresist material layer, that is corresponding to the second partial light transmission pattern, thereby forming the second spacer; and retaining a portion of the positive photoresist material layer, that is corresponding to the opaque pattern 13, thereby forming the first spacer. A height of the second spacer is less than a height of the first spacer, and is greater than a height of the black matrix layer. In this way, the formation of two spacers of different heights on the display substrate can maintain a cell thickness of a liquid crystal display device in a better manner.

Further, when the mask plate 1 further includes a second partial light transmission pattern that is corresponding to a second spacer of the display substrate, and the second partial light transmission pattern has a light transmittance greater than a light transmittance of the first partial light transmission pattern 12, the method specifically includes: forming a light-shielding negative photoresist material layer; exposing the negative photoresist material layer with the above mask plate 1; after developing, retaining a portion of the negative photoresist material layer, that is corresponding to the light transmission pattern 11, thereby forming the first spacer; removing a portion of the negative photoresist material layer, that is corresponding to the first partial light transmission pattern 12, thereby forming the black matrix layer; removing a portion of the negative photoresist material layer, that is corresponding to the second partial light transmission pattern, thereby forming the second spacer; and removing a portion of the negative photoresist material layer, that is corresponding to the opaque pattern 13. A height of the second spacer is less than a height of the first spacer, and is greater than a height of the black matrix layer. In this way, the formation of two spacers of different heights on the display substrate can maintain a cell thickness of a liquid crystal display device in a better manner.

Further, after simultaneously forming the black matrix pattern and the first spacer of the display substrate by means of one exposure development process, the method further includes: forming a color filtering unit in the pixel areas defined by the black matrix pattern; and covering the color filtering unit with a transparent conductive layer. The transparent conductive layer may be taken as a common electrode.

Further, before simultaneously forming the black matrix pattern and the first spacer of the display substrate by means of one exposure development process, the method further includes: forming a color filtering unit on a base substrate. Then, after simultaneously forming the black matrix pattern and the first spacer of the display substrate by means of one exposure development process, the method further includes: forming a transparent conductive layer. The transparent conductive layer may be taken as a common electrode.

The method for manufacturing display substrates according to the embodiments of the present disclosure will be described in details hereinafter with examples in conjunction with drawings.

### First Example

In this example, one manufacturing process for the display substrates includes insteps as follows: black matrix pattern 6 and spacer 7->red filtering unit 8->blue filtering unit 9->green filtering unit 10->transparent conductive layer 11. As shown in FIG. 4 to FIG. 8, the method for manufacturing display substrates according to this example includes the following steps.

Step 1 is to provide a base substrate 3, and form the spacer 7 and the black matrix pattern 6 on the base substrate 3 by means of one exposure development process.

The base substrate 3 may be a glass substrate or a quartz substrate. Specifically, after forming a light-shielding positive photoresist material layer on the base substrate 3, the light-shielding positive photoresist material layer is exposed with the mask plate 1 as shown in FIG. 1. The exposure process is shown in FIG. 3, the photoresist material corresponding to the light transmission pattern 11 is exposed to light and is developed due to cross-linking reaction, and then is removed away after being developed with a gap left for subsequently forming the color filtering unit. The photoresist material corresponding to the first partial light transmission pattern 12 is partially exposed and then forms the black matrix pattern 6 after being developed. The photoresist material corresponding to the opaque pattern 13, is not exposed and then forms the spacer 7 after being developed. The spacer 7 is used to maintain the cell thickness of the liquid crystal display device.

Step 2 is to form a color filtering unit on the base substrate 3 which is processed in the step 1.

As shown in FIG. 5, red photoresist material is first coated on the base substrate 3 which is processed in the step 1, thereby forming a red filtering unit 8. The red photoresist material is negative photoresist, and is exposed with a mask plate for manufacturing the red filtering unit 8. The negative photoresist is exposed to light and cross-linking reaction occurs. After being developed, a portion of the red photoresist material, that is not exposed to light, is removed away. When coating the red photoresist material, since the spacer is also coated with the red photoresist material, in order to ensure the height of the spacer 7, the mask plate 1 for manufacturing the red filtering unit 8 also needs to shield the spacer 7, thereby ensuring that the red photoresist material coated on the spacer 7 is not exposed to light and is developed.

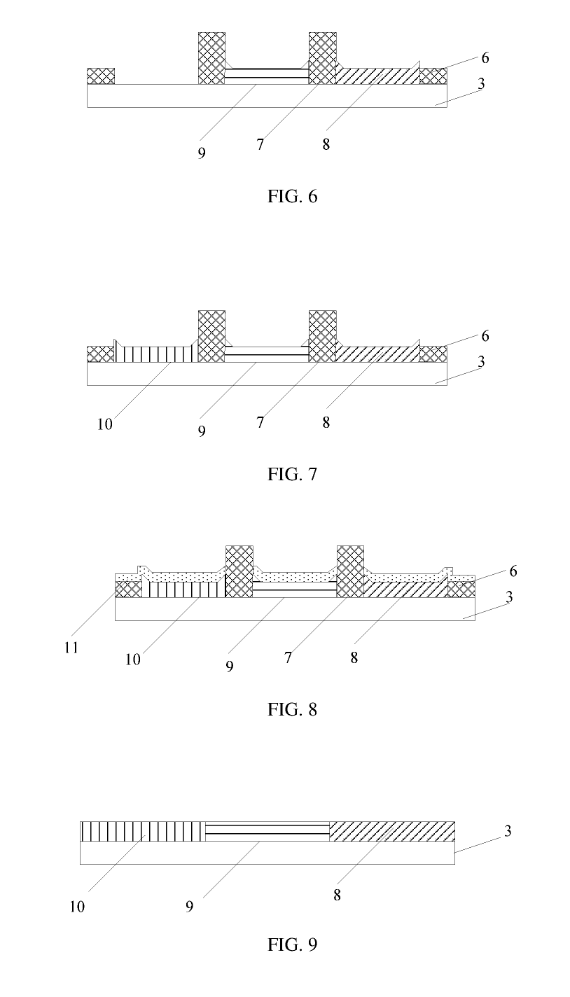

Subsequently, as shown in FIG. 6, blue photoresist material is coated on the base substrate 3 with the red photoresist material formed thereon, thereby forming a blue filtering unit 9. The blue photoresist material is negative photoresist, and is exposed with a mask plate for manufacturing the blue filtering unit 9. The negative photoresist is exposed to light and cross-linking reaction occurs. After being developed, a portion of the blue photoresist material, that is not exposed to light, is removed away. When coating the blue photoresist material, since the spacer 7 is also coated with the blue photoresist material, in order to ensure the height of the spacer 7, the mask plate 1 for manufacturing the blue filtering unit 9 also needs to shield the spacer 7, thereby ensuring that the blue photoresist material coated on the spacer 7 is not exposed to light and is developed.

Then, as shown in FIG. 7, green photoresist material is coated on the base substrate 3 with the blue photoresist material formed thereon, thereby forming a green filtering unit 10. The green photoresist material is negative photoresist, and is exposed with a mask plate for manufacturing the green filtering unit 10. The negative photoresist is exposed to light and cross-linking reaction occurs. After being developed, a portion of the green photoresist material, that is not exposed to light, is removed away. When coating the green photoresist material, since the spacer 7 is also coated with the green photoresist material, in order to ensure the height of the spacer 7, the mask plate 1 for manufacturing the green filtering unit 10 also needs to shield the spacer 7, thereby ensuring that the green photoresist material coated on the spacer 7 is not exposed to light and is developed.

In this example, the color filtering units may be formed in an order of the red filtering unit 8->the blue filtering unit 9->the green filtering unit 10. Of course, the color filtering units may be formed in other orders.

Step 3 is to form a transparent conductive layer on the base substrate 3 which is processed in the step 2.

As shown in FIG. 8, the transparent conductive layer may be deposited on the base substrate 3 which is processed in the step 2 by means of sputtering or thermal evaporation. The transparent conductive layer may be ITO, IZO or other transparent metal oxides. The transparent conductive layer may be used as a common electrode. Since the spacer 7 is in a non-display region and a thickness of the transparent conductive layer is smaller, the transparent conductive layer may be normally deposited on the base substrate 3 with the spacer 7 formed thereon. After formation of the transparent conductive layer, the formation of the display substrate is completed.

In this example, the height of the spacer 7 may be measured from a surface of the base substrate 3, which is taken as a reference surface. In this way, the cell thickness of the liquid crystal display device may be accurately controlled.

### Second Example

In this example, one manufacturing process for the display substrates includes insteps as follows: red filtering unit 8->blue filtering unit 9->green filtering unit 10->black matrix pattern 6 and spacer 7->transparent conductive layer 11. As shown in FIG. 9 to FIG. 1, the method for manufacturing display substrates according to this example includes the following steps.

Step 1 is to provide a base substrate 3, and form a color filtering unit on the base substrate 3.

The base substrate 3 may be a glass substrate or a quartz substrate. As shown in FIG. 9, red photoresist material is first coated on the base substrate 3. The red photoresist material is negative photoresist material, and is exposed with a mask plate 1 for manufacturing the red filtering unit 8. The negative photoresist is exposed to light and cross-linking reaction occurs. After being developed, a portion of the red photoresist material, that is not exposed to light, is removed away. A portion of the red photoresist material, that is exposed to light, is retained to form the red filtering unit 8.

Subsequently, blue photoresist material is coated on the base substrate 3 with the red filtering unit 8 formed thereon, thereby forming a blue filtering unit 9. The blue photoresist material is negative photoresist, and is exposed with a mask plate 1 for manufacturing the blue filtering unit 9. The negative photoresist is exposed to light and cross-linking reaction occurs. After being developed, a portion of the blue photoresist material, that is not exposed to light, is removed away. A portion of the blue photoresist material, that is exposed to light, is retained to form the blue filtering unit 9.

Then, green photoresist material is coated on the base substrate 3 with the blue filtering unit 9 formed thereon, thereby forming a green filtering unit 10. The green photoresist material is negative photoresist, and is exposed with a mask plate 1 for manufacturing the green filtering unit 10. The negative photoresist is exposed to light and cross-linking reaction occurs. After being developed, a portion of the green photoresist material, that is not exposed to light, is removed away. A portion of the green photoresist material, that is exposed to light, is retained to form the green filtering unit 10.

In this example, the color filtering units may be formed in an order of the red filtering unit 8->the blue filtering unit 9->the green filtering unit 10. Of course, the color filtering units may be formed in other orders.

In this example, there is no overlapping region between the color filtering units as well as there is no overlapping region between the black matrix pattern 6 and the color filtering units, thus, the segment difference caused by overlapping of the black matrix pattern 6 and the color filter units may be eliminated, thereby facilitating flattening of the color filter units, coating of alignment layers in the cell process, and improving and prevent poor rubbing orientation.

Step 2 is to form the spacer 7 and the black matrix pattern 6 on the base substrate 3 which is processed in the step 1, by means of one exposure development process.

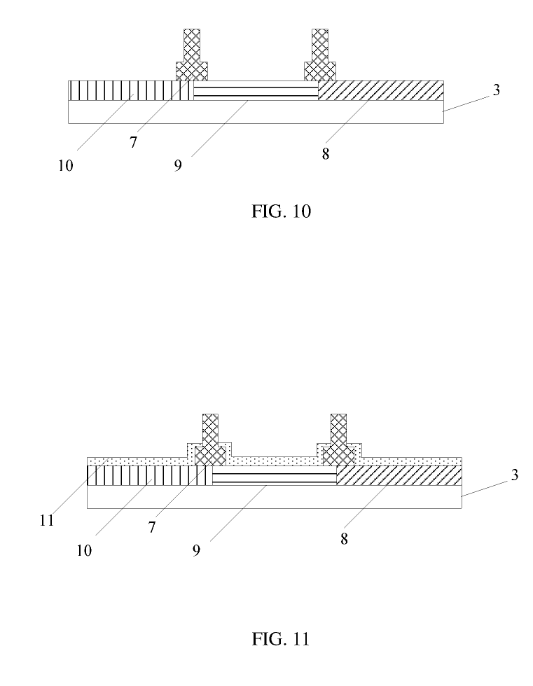

As shown in FIG. 10, a light-shielding positive photoresist material layer is formed on the base substrate 3 which is processed in the step 1. The light-shielding positive photoresist material layer is exposed with the mask plate 1 as shown in FIG. 1. The exposure process is shown in FIG. 3, the photoresist material corresponding to the light transmission pattern 11 is exposed to light and is developed due to cross-linking reaction, and then is removed away after being developed with a gap left. The photoresist material corresponding to the first partial light transmission pattern 12 is partially exposed and then forms the black matrix pattern 6 after being developed. The photoresist material corresponding to the opaque pattern 13, is not exposed and then forms the spacer 7 after being developed. The spacer 7 is used to maintain the cell thickness of the liquid crystal display device.

Step 3 is to form a transparent conductive layer 11 on the base substrate 3 which is processed in the step 2.

As shown in FIG. 11, the transparent conductive layer may be deposited on the base substrate 3 which is processed in the step 2 by means of sputtering or thermal evaporation. The transparent conductive layer may be ITO, IZO or other transparent metal oxides. The transparent conductive layer may be used as a common electrode. Since the spacer 7 is in a non-display region and a thickness of the transparent conductive layer is smaller, the transparent conductive layer may be normally deposited on the base substrate 3 with the spacer 7 formed thereon. After formation of the transparent conductive layer, the formation of the display substrate is completed.

One embodiment of the present disclosure further provides a display substrate which may be manufactured according to the above method.

One embodiment of the present disclosure further provides a display panel including the above display substrate.

One embodiment of the present disclosure further provides a display device including the above display panel. The display device may be any product or component having display function, such as a liquid crystal television, a liquid crystal monitor, a digital frame, a mobile phone or tablet computer. The display device further includes a flexible circuit board, a printed circuit board and a back plate.

Unless otherwise defined, any technical or scientific terms used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than being limited to physical or mechanical connection. Such words as “on/above”, “under/below”, “left” and “right” are merely used to represent relative position relationship, and when an absolute position of an object is changed, the relative position relationship will be changed too.

The above are merely the preferred embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

1. A mask plate for manufacturing a display substrate, the mask plate comprising:
a light transmission pattern corresponding to a color filtering unit of the display substrate;
a first partial light transmission pattern corresponding to a black matrix pattern of the display substrate; and
an opaque pattern corresponding to a first spacer of the display substrate.

2. The mask plate of claim 1, wherein the mask plate further includes a second partial light transmission pattern that is corresponding to a second spacer of the display substrate; and the second partial light transmission pattern has a light transmittance less than a light transmittance of the first partial light transmission pattern.

3. The mask plate of claim 2, wherein the light transmittance of the first partial light transmission pattern is 30%-50%, and the light transmittance of the second partial light transmission pattern is 10%-18%.

4. A mask plate for manufacturing a display substrate, the mask plate comprising:
an opaque pattern corresponding to a color filtering unit of the display substrate;
a first partial light transmission pattern corresponding to a black matrix pattern of the display substrate; and
a light transmission pattern corresponding to a first spacer of the display substrate.

5. The mask plate of claim 4, wherein the mask plate further includes a second partial light transmission pattern that is corresponding to a second spacer of the display substrate; and the second partial light transmission pattern has a light transmittance greater than a light transmittance of the first partial light transmission pattern.

6. The mask plate of claim 5, wherein the light transmittance of the second partial light transmission pattern is 30%-50%, and the light transmittance of the first partial light transmission pattern is 10%-18%.

7. A method for manufacturing a display substrate, comprising:
simultaneously forming a black matrix pattern and a first spacer of the display substrate with the mask plate of claim 1 through one exposure development process.

8. The method of claim 7, wherein simultaneously forming a black matrix pattern and a first spacer of the display substrate with the mask plate through one exposure development process includes:
forming a light-shielding positive photoresist material layer; exposing the positive photoresist material layer with the mask plate;
after developing, removing a portion of the positive photoresist material layer that corresponds to the light transmission pattern;
removing a portion of the positive photoresist material layer that corresponds to the first partial light transmission pattern, thereby forming the black matrix layer; and
retaining a portion of the positive photoresist material layer that corresponds to the opaque pattern, thereby forming the first spacer.

9. The method of claim 7, wherein after the simultaneously forming a black matrix pattern and a first spacer of the display substrate with the mask plate through one exposure development process, the method further includes:
forming a color filtering unit in pixel areas defined by the black matrix pattern; and
covering the color filtering unit with a transparent conductive layer.

10. The method of claim 7, wherein:
before the simultaneously forming a black matrix pattern and a first spacer of the display substrate with the mask plate through one exposure development process, the method further includes: forming a color filtering unit on a base substrate, and
after simultaneously forming a black matrix pattern and a first spacer of the display substrate with the mask plate through one exposure development process, the method further includes: forming a transparent conductive layer.

11. A method for manufacturing a display substrate, comprising:
simultaneously forming a black matrix pattern and a first spacer of the display substrate with the mask plate of claim 2 through one exposure development process.

12. The method of claim 11, wherein simultaneously forming a black matrix pattern and a first spacer of the display substrate with the mask plate through one exposure development process includes:
forming a light-shielding positive photoresist material layer, and exposing the positive photoresist material layer with the mask plate;
after developing, removing a portion of the positive photoresist material layer corresponding to the light transmission pattern;
removing a portion of the positive photoresist material layer corresponding to the first partial light transmission pattern, thereby forming the black matrix layer;
removing a portion of the positive photoresist material layer corresponding to the second partial light transmission pattern, thereby forming the second spacer; and
retaining a portion of the positive photoresist material layer corresponding to the opaque pattern, thereby forming the first spacer,
wherein a height of the second spacer is less than a height of the first spacer, and is greater than a height of the black matrix layer.

13. A method for manufacturing a display substrate, comprising:
simultaneously forming a black matrix pattern and a first spacer of the display substrate with the mask plate of claim 4 through one exposure development process.

14. The method of claim 13, wherein simultaneously forming a black matrix pattern and a first spacer of the display substrate with the mask plate through one exposure development process includes:
forming a light-shielding negative photoresist material layer;
exposing the negative photoresist material layer with the mask plate;
after developing, retaining a portion of the negative photoresist material layer corresponding to the light transmission pattern, thereby forming the first spacer;
removing a portion of the negative photoresist material layer corresponding to the first partial light transmission pattern, thereby forming the black matrix layer; and
removing a portion of the negative photoresist material layer corresponding to the opaque pattern.

15. A method for manufacturing a display substrate, comprising:
simultaneously forming a black matrix pattern and a first spacer of the display substrate with the mask plate of claim 5 through one exposure development process.

16. The method of claim 15, wherein simultaneously forming a black matrix pattern and a first spacer of the display substrate with the mask plate through one exposure development process includes:
forming a light-shielding negative photoresist material layer;
exposing the negative photoresist material layer with the above mask plate;
after developing, retaining a portion of the negative photoresist material layer corresponding to the light transmission pattern, thereby forming the first spacer;
removing a portion of the negative photoresist material layer corresponding to the first partial light transmission pattern, thereby forming the black matrix layer;
removing a portion of the negative photoresist material layer corresponding to the second partial light transmission pattern, thereby forming the second spacer; and
removing a portion of the negative photoresist material layer corresponding to the opaque pattern,
wherein a height of the second spacer is less than a height of the first spacer, and is greater than a height of the black matrix layer.
